(19) United States
(12) Patent Application Publication
(10) Pub. No.: US 2025/0120291 A1
(43) Pub. Date: Apr. 10, 2025

(54) DISPLAY DEVICE

(71) Applicant: SAMSUNG DISPLAY CO., LTD., YONGIN-SI (KR)

(72) Inventors: YONGCHAN JU, Yongin-si (KR); YEONGUK KIM, Yongin-si (KR); HEEYEON PARK, Yongin-si (KR); CHANGYEONG SONG, Yongin-si (KR); HYEIN JUNG, Yongin-si (KR); JAE HEUNG HA, Yongin-si (KR)

(21) Appl. No.: 18/904,607

(22) Filed: Oct. 2, 2024

(30) Foreign Application Priority Data
Oct. 6, 2023 (KR) 10-2023-0133412

(51) Int. Cl. H10K 59/80

(52) U.S. Cl. CPC H10K 59/8731

(57) ABSTRACT

Disclosed is a display device having enhanced touch sensitivity by providing an organic encapsulation layer with a low dielectric constant. The display device includes a substrate, a transistor located on the substrate, a light emitting diode electrically connected to the transistor, a first inorganic encapsulation layer located on the light emitting diode, the organic encapsulation layer located on the first inorganic encapsulation layer, and a second inorganic encapsulation layer located on the organic encapsulation layer, in which the organic encapsulation layer includes a plurality of composites, and each of the plurality of composites comprising a plurality of nucleotides and a hollow polymer.

### CROSS-REFERENCE TO RELATED APPLICATION

This application claims priority under 35 U.S.C. § 119 to Korean Patent Application No. 10-2023-0133412, filed on Oct. 6, 2023, in the Korean Intellectual Property Office, the entire contents of which are incorporated by reference herein.

### TECHNICAL FIELD

The present invention relates to a display device.

### DISCUSSION OF RELATED ART

A display device includes pixels, and can display an image on a display screen by controlling the brightness of each pixel. The pixels are formed on a display panel. A touch sensor capable of detecting a user's touch may be provided on the display panel. For example, the display device may include a display panel, and the display panel may include a touch sensor, or a panel including a touch sensor may be attached to the display panel. The sensitivity of the touch sensor may be affected by the component(s) adjacent to the touch sensor. For example, parasitic capacitance formed between the adjacent component(s) and the touch sensor may affect the sensitivity of the touch sensor.

### SUMMARY

Embodiments of the present invention provide a display device with enhanced touch sensitivity.

A display device according to an embodiment of the present invention includes a substrate, a transistor located on the substrate, a light emitting diode electrically connected to the transistor, a first inorganic encapsulation layer located on the light emitting diode, an organic encapsulation layer located on the first inorganic encapsulation layer, and a second inorganic encapsulation layer located on the organic encapsulation layer, in which the organic encapsulation layer includes a plurality of composites, and each of the plurality of composites includes a plurality of nucleotides and a hollow polymer.

Each of the plurality of composites may include deoxyribonucleic acid (DNA) in which the plurality of nucleotides are bonded together.

The deoxyribonucleic acid (DNA) may contain empty space therein.

The hollow polymer may be located within the deoxyribonucleic acid (DNA).

The hollow polymer may include polystyrene.

The organic encapsulation layer may further include a first organic material, and the plurality of composites may be dispersed within the first organic material.

The first organic material may include at least one of an acrylate-based compound, an epoxy-based compound, a vinyl-based compound, or a urethane-based compound.

Each of the plurality of composites may further include a ligand bound to the surface. The ligand may be bound to a deoxyribonucleic acid (DNA).

The ligand may include a compound of a family the same as that of the first organic material.

The ligand may include at least one of an acrylate-based compound, an epoxy-based compound, a vinyl-based compound, or a urethane-based compound.

A display device according to an embodiment of the present invention includes a substrate, a transistor located on the substrate, a light emitting diode electrically connected to the transistor, an organic encapsulation layer located on the light emitting diode, and a touch sensor located on the organic encapsulation layer, in which the organic encapsulation layer includes a plurality of composites dispersed within the organic encapsulation layer, and each of the plurality of composites includes a hollow polymer and deoxyribonucleic acid (DNA) surrounding the hollow polymer.

Each of the plurality of composites may further include a first space included in each of the hollow polymers and a second space included in the deoxyribonucleic acid (DNA).

The hollow polymer may be located in the second space of the deoxyribonucleic acid (DNA).

The hollow polymer may include polystyrene.

The organic encapsulation layer may further include a first organic material, and the plurality of composites may be dispersed within the first organic material.

The first organic material may include at least one of an acrylate-based compound, an epoxy-based compound, a vinyl-based compound, or a urethane-based compound.

Each of the plurality of composites may further include a ligand bound to the surface of the deoxyribonucleic acid (DNA).

The ligand may include a compound of a family the same as that of the first organic material.

The ligand may include at least one of an acrylate-based compound, an epoxy-based compound, a vinyl-based compound, or a urethane-based compound.

According to an embodiment of the present invention, the touch sensitivity of the display device may be enhanced by providing an organic encapsulation layer with a low dielectric constant.

### BRIEF DESCRIPTION OF THE DRAWINGS

Embodiments of the present invention will be more clearly understood from the following detailed description taken in conjunction with the accompanying drawings in which:

FIG. 1 is a schematic exploded perspective view of a display device according to an embodiment of the present invention;

FIG. 2 is a perspective view of a display device according to an embodiment of the present invention;

FIG. 3 is a top view of a touch sensor according to an embodiment of the present invention;

FIG. 4 is a schematic cross-sectional view of a display panel according to an embodiment of the present invention;

FIG. 5 is a cross-sectional view of an organic encapsulation layer according to an embodiment of the present invention;

FIG. 6 is a diagram of a composite according to an embodiment of the present invention;

FIG. 7 is a diagram of a method for manufacturing a composite according to an embodiment of the present invention; and

FIG. 8 is a diagram of a composite according to an embodiment of the present invention.

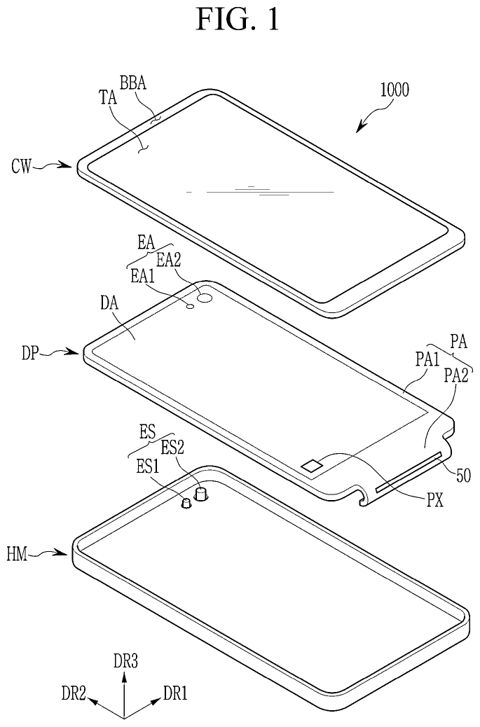

Since the drawings in FIGS. 1-8 are intended for illustrative purposes, the elements in the drawings are not necessarily drawn to scale. For example, some of the elements may be enlarged or exaggerated for clarity purpose.

### DETAILED DESCRIPTION OF THE EMBODIMENTS

Hereinafter, with reference to the attached drawings, various embodiments of the present invention will be described in detail so that those skilled in the art can easily implement the present invention.

The present invention may be implemented in many different forms and is not limited to the embodiments described herein.

To clearly explain the present invention, parts that are not relevant to the description are omitted, and identical or similar components are assigned the same reference numerals (or characters) throughout the specification.

When a part of a layer, membrane, region, or plate is said to be “above” or “on” another part, this includes not only cases where it is “directly above” another part, but also cases where there is an intervening part present in between.

Conversely, when a part is said to be “right on top” of another part, it means that there is no other part in between.

It will be understood, being “above” or “on” a reference part means being located above or below the reference part, and does not necessarily mean being located “above” or “on” it in the direction opposite to gravity. It will be understood that the spatially relative terms are intended to encompass different orientations of the device in use or in operation, in addition to the orientation depicted in the figures.

Throughout the specification, when a part is said to “include” a certain component, this means that it may further include other components rather than excluding other components, unless specifically stated to the contrary.

Throughout the specification, when reference is made to “on a plane” this means when the target part is viewed from above, and when reference is made to “in cross-section” this means when a cross-section of the target part is cut vertically and viewed from the side.

Hereinafter, a display device according to an embodiment of the present invention will be described with reference to FIGS. 1 to 4.

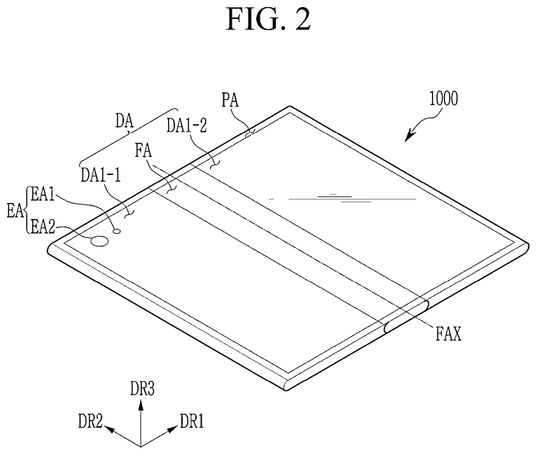

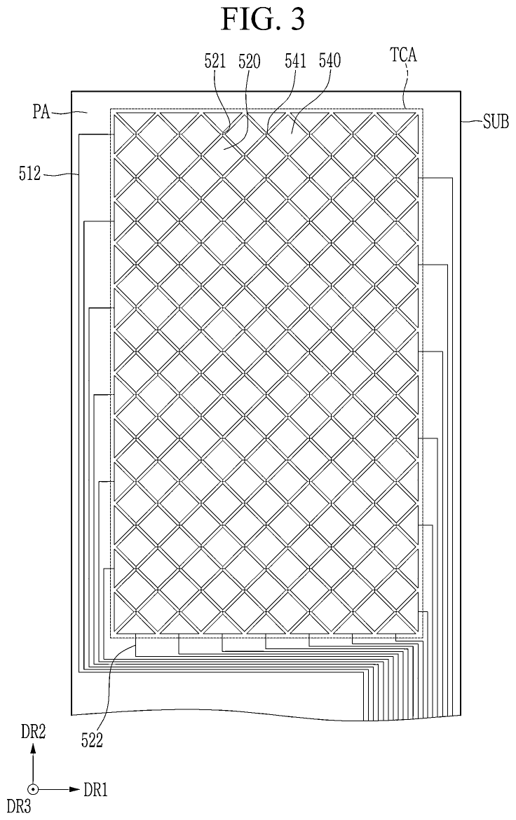

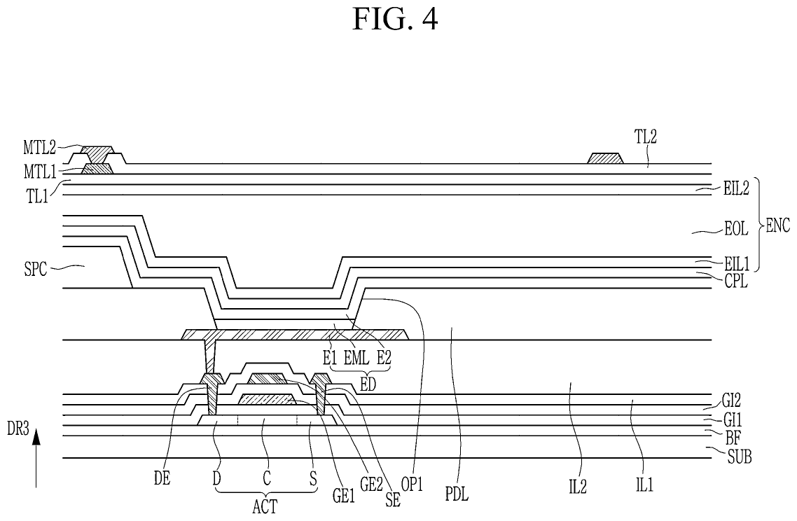

FIG. 1 is a schematic exploded view of a display device according to an embodiment of the present invention, FIG. 2 is a perspective view of a display device according to an embodiment of the present invention, FIG. 3 is a plan view of a touch detection part according to an embodiment of the present invention, and FIG. 4 is a schematic cross-sectional view of a display panel according to an embodiment of the present invention.

Referring to FIG. 1, the display device 1000 according to an embodiment of the present invention is a device for displaying videos or still images, and may be used as a display screen for various products such as, for example, mobile phones, smart phones, tablet personal computers (tablet PCs), mobile communication terminals, electronic notebooks, e-books, portable multimedia players (PMPs), navigation device, Ultra Mobile PCs (UMPCs), and not only portable electronic devices, but also televisions, laptops, monitors, billboards, and the Internet of Things (IoT).

The display device 1000 according to an embodiment of the present invention may be mounted on a wearable device such as, for example, a smart watch, a watch phone, a glasses-type display, and a head-mounted display (HMD).

The display device 1000 according to an embodiment of the present invention may be used as, for example, a car dashboard, a Center Information Display (CID) placed on the center fascia or dashboard of a car, a room mirror display replacing the side mirror of a car, or a display placed on the back of the front seat for rear-seat entertainment in a car.

FIG. 1 shows the display device 1000 being used as a smart phone, for convenience of explanation.

The display device 1000 may display an image in the third direction DR3 on a display surface parallel to each of the first and second directions DR1 and DR2.

The display surface on which the image is displayed may correspond to the front surface of the display device 1000 and the front surface of the cover window CW.

Images may include static images as well as dynamic images (moving images).

In an embodiment of the present invention, the front (or top) and back (or bottom) surfaces of each member are defined based on the direction in which the image is displayed. The front and back surfaces are opposed to each other in the third direction DR3, and the normal directions of each of the front and back surfaces may be parallel to the third direction DR3.

The separation distance between the front and back surfaces in the third direction DR3 may correspond to the thickness of the display panel in the third direction DR3.

The display device 1000 according to an embodiment of the present invention may detect a user's input applied from the outside.

The user's input may include various types of external inputs, such as, for example, parts of the user's body, light, heat, or pressure. However, the present invention is not limited thereto.

The user's input may be provided in various forms, and the display device 1000 may also detect the user's input applied to the side or back of the display device 1000 depending on the structure of the display device 1000.

The display device 1000 may include a cover window CW, a housing HM, a display panel DP, and an optical element ES.

In an embodiment of the present invention, the cover window CW and the housing HM may be combined to configure the exterior of the display device 1000. For example, the display panel DP may be enclosed by the cover window CW and the housing HM. In other words, the cover window CW may couple with the housing HM to fix in place the display panel DP.

The cover window CW may include an insulating panel. For example, the cover window CW may be made of, for example, glass, plastic, or a combination thereof.

The front of the cover window CW may define the front of the display device 1000, and may include a transmission area TA and a blocking area BBA. The display device 1000 displays the image in the transmission area TA.

The transmission area TA may be an optically transparent area. For example, the transmission area TA may be an area with a visible light transmittance of about 90% or more. When the term “about” is used in this specification in connection with a numerical value, it is intended that the associated numerical value includes a tolerance of up to +10% around the stated numerical value.

The blocking area BBA may define the shape of the transmission area TA.

The blocking area BBA is adjacent to the transmission area TA and may surround the transmission area TA. For example, the blocking area BBA may be located outside the transmission area TA. However, the present disclosure is not limited thereto, and the blocking area BBA may be disposed adjacent to only one side of the transmission area TA.

The blocking area BBA may be an area with relatively low light transmittance compared to the transmission area TA.

The blocking area BBA may include an opaque material that blocks light.

The blocking area BBA may have a predetermined color.

The blocking area BBA may be defined by a bezel layer provided separately from the transparent substrate defining the transparent area TA, or may be defined by an ink layer formed by inserting or coloring the transparent substrate.

The display panel DP may include a display pixel PX that displays an image and a driver 50, and the display pixel PX is located in the display area DA and the component area EA. The display panel DP may provide an image via an array of a plurality of the display pixels PX arranged in the display area DA. In an embodiment of the present invention, the display pixels PX may be arranged in various forms such as, for example, a stripe arrangement, a pentile arrangement, a mosaic arrangement, and the like, to implement the image. The plurality of display pixels PX may each emit, for example, red, green, blue, or white light.

The display panel DP may include a front surface including a display area DA and a non-display area PA outside the display area DA, with the non-display area PA at least partially overlapping the blocking area BBA of the cover window CW.

In an embodiment of the present invention, the display area DA and the component area EA are areas where images are displayed, including pixels, and at the same time, a touch sensor may be located on the upper side in the third direction DR3 of the pixels, which may be an area where external inputs are detected.

The transmission area TA of the cover window CW may at least partially overlap the display area DA and the component area EA of the display panel DP. For example, the transmission area TA may overlap the front surface of the display area DA and the component area EA, or may overlap at least a portion of the display area DA and the component area EA.

The user may view the image through the transmission area TA or provide external input based on the image. For example, the image generated by the display panel DP may be visible to a user from the outside by being displayed on a display surface of the display panel DP through the transmission area TA of the cover window CW, and the external input may be simultaneously sensed in the transmission area TA. However, the present invention is not limited thereto. For example, the area where an image is displayed and the area where external input is detected may be separated from each other.

The non-display area PA of the display panel DP may at least partially overlap the blocking area BBA of the cover window CW.

The non-display area PA may be an area covered by the blocking area BBA, and may be an area where the image is not displayed. For example, the blocking area BBA may cover the non-display area PA of the display device 1000 so as to prevent the non-display area PA from being visually recognized from the outside.

The non-display area PA is adjacent to the display area DA, and may surround the display area DA.

An image is not displayed in the non-display area PA, and a driving circuit or driving wiring for driving the display area DA may be disposed in the non-display area PA.

The non-display area PA may include a first non-display area PA1 located outside the display area DA and a second non-display area PA2 including the driver 50, connection wiring, and a bending area.

The first non-display area PA1 is located on three sides of the display area DA, and the second non-display area PA2 is located on the remaining side of the display area DA. A portion of the non-display area PA of the display panel DP may be curved.

At this time, part of the non-display area PA is directed toward the rear of the display device 1000, so that the blocking area BBA visible on the front of the display device 1000 may be reduced, and the second non-display area PA2 may be bent and placed on the back of the display area DA and then assembled.

The component area EA of the display panel DP may include a first component area EA1 and a second component area EA2. The component area CA may be located on a side portion, for example, an upper right portion or an upper left portion, of the main display area DA having the substantially quadrangular shape. However, the present invention is not limited thereto.

The first component area EA1 and the second component area EA2 may be at least partially surrounded by the display area DA. In an embodiment of the present invention, the first component area EA1 and the second component area EA2 may be entirely surrounded by the display area DA.

The first component area EA1 and the second component area EA2 are shown spaced apart from each other, but are not limited thereto and may be at least partially connected.

The first component area EA1 and the second component area EA2 may be areas in which an optical element that uses infrared light, visible light, or sound is placed below the first component area EA1 and the second component area EA2.

The display area (DA; hereinafter also referred to as the main display area) and the component area EA are formed with a plurality of light emitting diodes and a plurality of pixel circuit units that generate and transmit light emitting current to each of the plurality of light emitting diodes. In an embodiment of the present invention, the light emitting diode may be an organic light emitting diode including an organic emission layer.

Here, one light emitting diode and one pixel circuit unit are called a pixel PX.

One pixel circuit unit and one light emitting diode may be formed in a one-to-one ratio in the display area DA and the component area EA.

The first component area EA1 may include a display layer including a plurality of pixels and a transmission part through which light and/or sound may pass.

The transmission part is located between adjacent pixels and is composed of a layer through which light and/or sound may be transmitted. According to an embodiment of the present invention, when light is transmitted through the component area EA, a light transmittance may be equal to or greater than about 10%, for example, equal to or greater than 40%, 25%, 50%, 85%, or 90%. When the light is infrared rays, the component area EA may not have high transmittance in visible light.

The transmission part may be located between adjacent pixels, and depending on the embodiment, a layer that does not transmit light, such as a light blocking member, may overlap the first component area EA1.

The number of pixels (hereinafter referred to as resolution) per unit area of the pixels (hereinafter referred to as normal pixels) included in the display area DA and the pixels included in the first component area EA1 (hereinafter referred to as first component pixels) may be the same. In an embodiment of the present invention, the first component area EA1 and the display area DA may display an image individually or together.

The second component area EA2 includes an area composed of a transparent layer so that light may pass through (hereinafter also referred to as a light transmission area), and the light transmission area does not have a conductive layer or a semiconductor layer and includes a light blocking material. The layer, for example, the pixel defining layer and/or the light blocking member, may have a structure that does not block light by including an opening that overlaps a position corresponding to the second component area EA2.

The number of pixels per unit area of the pixels included in the second component area EA2 (hereinafter also referred to as second-component pixels) may be smaller than the number of pixels per unit area of the normal pixels included in the display area DA. As a result, the resolution of the second-component pixels may be lower than that of the normal pixels. In an embodiment of the present invention, an image displayed by the second component area EA2 may be an auxiliary image and may have a resolution less than that of an image displayed by the display area DA.

The driver 50 located in the second non-display area PA2 is electrically connected to the display area DA and the component area EA, and may transmit electrical signals to pixels in the display area DA and the component area EA.

The driver 50 may provide data signals to the pixels PX arranged in the display area DA. Alternatively, the driver 50 may include a touch driving circuit and may be electrically connected to the touch sensor disposed in the display area DA and/or the component area EA.

The driver 50 may include various circuits in addition to the above-described circuits or may be designed to provide various electrical signals to the display area DA.

The display device 1000 may have a pad portion located at the end of the second non-display area PA2, and the pad portion may be used to electrically connect a flexible printed circuit board (FPCB) including a driving chip.

The driving chip located on the flexible printed circuit board (FPCB) may include various driving circuits for driving the display device 1000 or a connector for power supply.

Depending on the embodiment, a rigid printed circuit board (PCB) may be used instead of a flexible printed circuit board (FPCB). In an embodiment of the present invention, the display device 1000 may include both the PCB and the FPCB with the driving chip located on the FPCB, the PCB may be connected with the FPCB so as to be electrically connected with the display panel DP. The FPCB may be connected with the display panel DP such that the display panel DP and the PCB are electrically connected.

The optical element ES may be disposed below the display panel DP.

The optical element ES may include a first optical element ES1 overlapping the first component area EA1 and a second optical element ES2 overlapping the second component area EA2.

The first optical element ES1 may use infrared rays, and in this case, a layer that does not transmit light, such as a light blocking member, may overlap the first component area EA1.

The first optical element ES1 may be an electronic element that uses light or sound. For example, the first optical element ES1 is a sensor that receives and uses light such as an infrared sensor, a sensor that outputs and detects light or sound to measure distance or recognize a fingerprint, etc., a small lamp that outputs light, or a speaker that outputs sound, etc.

In the case of electronic elements that use light, it goes without saying that light of various wavelength bands, such as, for example, visible light, infrared light, and ultraviolet light, may be used.

The second optical element ES2 is at least one of, for example, a camera, an IR camera, a dot projector, an IR illuminator, or a time-of-flight sensor (ToF sensor). Alternatively, the second optical element ES2 may be a solar cell, an illuminance sensor, a proximity sensor, a thermal detection sensor, or an iris sensor.

The housing HM may be combined with the cover window CW.

The cover window CW may be placed on the front of the housing HM.

The housing HM may be combined with the cover window CW to provide a predetermined accommodation space.

The display panel DP and the optical element ES may be accommodated in a predetermined accommodation space provided between the housing HM and the cover window CW. In addition to the display panel DP, components required to drive the display device 1000, for example, a power supply unit, such as, for example, a battery, a circuit board, or the like, may be mounted inside the housing HM.

The housing HM may include a material with relatively high rigidity. For example, the housing HM may include a plurality of frames and/or plates made of glass, plastic, or metal, or a combination thereof.

The housing HM may stably protect the components of the display device 1000 accommodated in the internal space from external shock. According to an embodiment of the present invention, the cover window CW and the housing HM may be combined to configure an exterior of the display device 1000.

Hereinafter, the structure of the display device 1000 according to an embodiment of the present invention will be looked at through FIG. 2.

FIG. 2 is a perspective view schematically showing a display device according to an embodiment of the present invention.

Description of the same components as those described above will be omitted, and the embodiment of FIG. 2 shows a foldable display device in which the display device 1000 is folded through the folding axis FAX.

Referring to FIG. 2, in an embodiment of the present invention, the display device 1000 may be a foldable display device.

The display device 1000 may be folded outward or inward based on the folding axis FAX.

When folded outward based on the folding axis FAX, the display surfaces of the display device 1000 are positioned on the outside in the third direction DR3 so that images may be displayed in both directions. For example, the images may be displayed on the front surface and the rear surface of the display device 1000 folded outward.

If it is folded inward based on the folding axis FAX, the display surface may not be visible from the outside.

In an embodiment of the present invention, the display device 1000 may include a display area DA, a component area EA, and a non-display area PA.

The display area DA may be divided into a 1-1 display area DA1-1, a 1-2 display area DA1-2, and a folding area FA. In an embodiment of the present invention, the 1-1 display area DA1-1 and the 1-2 display area DA1-2 may be non-folding areas.

The 1-1 display area DA1-1 and the 1-2 display area DA1-2 may be located on the left and right sides, respectively, based on (or centered on) the folding axis FAX, and the folding area FA may be located between the 1-1 display area DA1-1 and the 1-2 display area DA1-2.

When folded outward based on the folding axis FAX, the 1-1 display area DA1-1 and the 1-2 display area DA1-2 are located on both sides in the third direction DR3, and images may be displayed in both directions.

When folded inward based on the folding axis FAX, the 1-1 display area DA1-1 and the 1-2 display area DA1-2 may not be visible from the outside. The folding area FA may have a flat surface located on a plane the same as that of the surfaces of the 1-1 display area DA1-1 and the 1-2 display area DA1-2 in an unfolded state, but it may be folded or bent to have a curved surface.

Hereinafter, a touch sensor according to an embodiment of the present invention will be described with reference to FIG. 3. FIG. 3 is a schematic plan view of a touch sensor included in a display panel according to an embodiment of the present invention.

Referring to FIG. 3, a touch sensor area TCA including a plurality of sensing electrodes 520 and 540 to recognize a touch may be located above the display area DA and above the light emitting diode.

The touch sensor area TCA may be an area where the touch sensor is located, which is the area where external inputs are detected.

A signal line or voltage line (e.g., a driving voltage line, a driving low-voltage line, etc.) for transmitting a signal or voltage to a pixel formed in the display area DA may be located in the non-display area PA.

A plurality of sensing wires 512 and 522 may be further located in the non-display area PA.

A plurality of sensing wires 512 and 522 may be connected to a plurality of sensing electrodes 520 and 540.

The touch sensor area TCA may include a plurality of sensing electrodes 520 and 540.

The plurality of sensing electrodes 520 and 540 may include a plurality of first sensing electrodes 520 and a plurality of second sensing electrodes 540 that are electrically separated.

Depending on the embodiment, the plurality of first sensing electrodes 520 may be sensing input electrodes, and the plurality of second sensing electrodes 540 may be sensing output electrodes. However, the present invention is not limited thereto, and the plurality of first sensing electrodes 520 may be sensing output electrodes, and the plurality of second sensing electrodes 540 may be sensing input electrodes.

The plurality of first sensing electrodes 520 and the plurality of second sensing electrodes 540 may be distributed and arranged in a mesh form so as not to overlap each other. As each of the first sensing electrodes 520 and the second sensing electrodes 540 has a mesh shape, a parasitic capacitance between electrodes of the touch sensor area TCA and electrodes included in the display panel DP below the touch sensor area TCA may be reduced. Also, since the first sensing electrodes 520 and second sensing electrodes 540 do not overlap emission areas, the first sensing electrodes 520 and the second sensing electrodes 540 are not viewed by a user of the display device 1000.

The plurality of first sensing electrodes 520 are arranged along one of the column direction and the row direction (referring to FIG. 3, the second direction DR2). They are electrically connected to each other by a first sensing electrode connection part 521 (also called a bridge) to extend in the second direction DR2 (referring to FIG. 3, column direction). A plurality of columns of the first sensing electrodes 520 may be arranged to be spaced apart from each other in the first direction DR1.

The plurality of second sensing electrodes 540 are also arranged along the other of the column direction and the row direction (referring to FIG. 3, the first direction DR1). They are electrically connected to each other by the second sensing electrode connection part 541 to extend in the first direction DR1 (referring to FIG. 3, row direction). A plurality of rows of the second sensing electrodes 540 may be arranged to be spaced apart from each other in the second direction DR2.

The plurality of first sensing electrodes 520 and the plurality of second sensing electrodes 540 may be located on the same conductive layer.

Depending on the embodiment, the plurality of first sensing electrodes 520 and the plurality of second sensing electrodes 540 may be located in different conductive layers.

According to FIG. 3, the first sensing electrode 520 and the second sensing electrode 540 may have a diamond shape, but are not limited thereto, and depending on the embodiment, may have a polygonal shape such as a square or hexagon, or a circular or oval shape.

According to FIG. 3, the plurality of first sensing electrodes 520 and the plurality of second sensing electrodes 540 are shown as an integrated rhombus structure, but in reality, one rhombus structure has an opening and the linear structure has a mesh shape.

At this time, the opening may correspond to an area where the light emitting diode emits light upward. Additionally, depending on the embodiment, it may have a shape that further includes an extension part to enhance the sensitivity of the touch sensor.

The first sensing electrode 520 and the second sensing electrode 540 may be formed of a transparent conductor or an opaque conductor.

In an embodiment of the present invention, the first sensing electrode 520 and the second sensing electrode 540 may include transparent conductive oxide (TCO), and the transparent conductive oxide (TCO) may include one of indium tin oxide (ITO), indium-zinc oxide (IZO), zinc oxide (ZnO), indium oxide (In₂O₃), indium gallium oxide (IGO), aluminum zinc oxide (AZO), carbon nanotube (CNT), and graphene. However, the present invention is not limited thereto.

The first sensing electrode 520 and the second sensing electrode 540 may include a plurality of openings.

The openings formed in the sensing electrodes 520 and 540 serve to allow light emitted from the light emitting diode to be emitted to the front without interference. In an embodiment of the present invention, the sensing electrodes 520 and 540 may form three types of light-emitting openings distinguished from each other according to their sizes and shapes. Each of the three types of light emitting openings may correspond to each of the three light-emitting areas of display pixels PX emitting red, green and blue light, respectively.

When the first sensing electrode 520 and the second sensing electrode 540 are located on the same layer, one of the first sensing electrode connection part 521 and the second sensing electrode connecting part 541 is connected to the first sensing electrode 520, and may be located on the same layer as the second sensing electrode 540, and the remaining one may be located on a different layer from the first sensing electrode 520 and the second sensing electrode 540. As a result, the plurality of first sensing electrodes 520 and the plurality of second sensing electrodes 540 may be electrically separated.

The sensing electrode connection located on another layer may be located on the upper or lower layer of the first sensing electrode 520 and the second sensing electrode 540, and in the embodiment described below, the description of the lower layer—that is, the layer closer to the substrate—will focus on an embodiment in which the sensing electrode connection is located.

A plurality of sensing wires 512 and 522 connected to a plurality of first sensing electrodes 520 and a plurality of second sensing electrodes 540 are located in the non-display area PA.

The plurality of first sensing wires 512 may each be connected to one row of the plurality of rows of the second sensing electrodes 540 extending in the first direction DR1, and the plurality of second sensing wires 522 may each be connected to one column of the plurality of columns of the first sensing electrodes 520 extending in the second direction DR2.

FIG. 3 shows a mutual-cap type sensing unit that detects a touch using two sensing electrodes 520 and 540. However, depending on the embodiment, it may be formed as a self-cap type sensing unit that detects touch using only one sensing electrode. In other words, the touch sensor may sense an external input based on a sensing result of change in mutual capacitance between the first sensing electrodes 520 and the second sensing electrodes 540, or may sense an external input based on a sensing result of change in self-capacitance of each of the first sensing electrodes 520 and the second sensing electrodes 540.

Hereinafter, a composite according to an embodiment of the present invention will be described with reference to FIGS. 4 to 7.

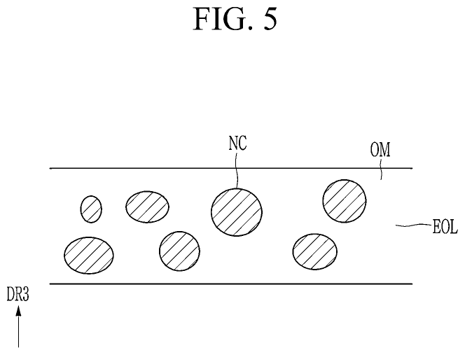

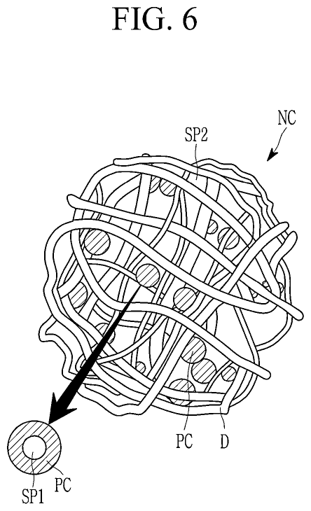

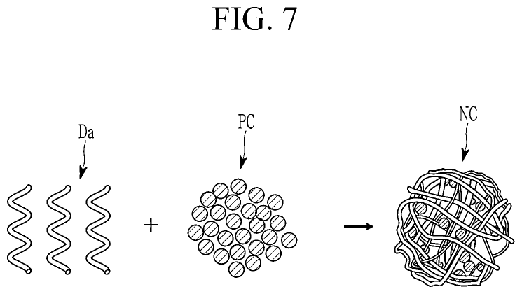

FIG. 4 is a schematic cross-sectional view of a display panel according to an embodiment of the present invention, FIG. 5 is a cross-sectional view of an organic encapsulation layer according to an embodiment of the present invention, FIG. 6 is a view of a composite according to an embodiment of the present invention, and FIG. 7 is a diagram of a manufacturing method of a composite according to an embodiment of the present invention.

First, referring to FIG. 4, the substrate SUB may include a material with rigid properties such as glass or a flexible material that may be bent such as plastic or polyimide.

A buffer layer BF may be further positioned on the substrate SUB to flatten the surface of the substrate SUB and block penetration of impure elements. For example, the buffer layer BF may enhance a bonding force between the substrate SUB and the semiconductor layer ACT. The buffer layer BF may be configured to reduce or block penetration of foreign materials, moisture, or ambient air from a bottom portion of the substrate SUB and may provide a flat surface on the substrate SUB.

The buffer layer BF may include an inorganic material—for example, an inorganic insulating material such as, for example, silicon nitride (SiNₓ), silicon oxide (SiOₓ), or silicon oxynitride (SiOₓN_{y}).

Depending on the embodiment, the buffer layer BF may have a single-layer or multi-layer structure including one or more inorganic insulating materials. For example, the buffer layer BFL may include a structure in which a silicon oxide (SiOₓ) layer and a silicon nitride (SiNₓ) layer are stacked alternately.

A barrier layer may be further positioned on the substrate SUB.

At this time, the barrier layer may be located between the substrate SUB and the buffer layer BF.

The barrier layer may include an inorganic insulating material such as silicon nitride (SiNₓ), silicon oxide (SiOₓ), or silicon oxynitride (SiOₓN_{y}).

The barrier layer may have a single-layer or multi-layer structure containing one or more inorganic insulating materials.

The semiconductor layer ACT may be located on the substrate SUB.

The semiconductor layer ACT may include any one of amorphous silicon (a-Si), polycrystalline silicon (pc-Si), and an oxide semiconductor. For example, the semiconductor layer ACT may be an oxide semiconductor containing low-temperature polysilicon (LTPS) or at least one of, for example, zinc (Zn), indium (In), gallium (Ga), tin (Sn), or mixtures thereof. For example, the semiconductor layer ACT may include indium-gallium-zinc oxide (IGZO).

The semiconductor layer ACT may include a channel region C, a source region S, and a drain region D that are divided depending on whether or not the semiconductor layer is doped with impure elements. The source region S and the drain region D may be doped with an N-type dopant or a P-type dopant. The N-type dopants may include, for example, phosphorus (P), arsenic (As), etc. The P-type dopants may include, for example, boron (B), aluminum (Al), gallium (Ga), etc.

The source region S and drain region D may have conductive characteristics corresponding to the conductors. The source region S and drain region D may extend from the channel region C in directions facing away from each other in a cross-sectional view, and may be arranged respectively on opposite sides of the channel region C.

The first gate insulating layer GI1 may cover the semiconductor layer ACT and the substrate SUB.

The first gate insulating layer GI1 may include an inorganic insulating material such as, for example, silicon nitride (SiNₓ), silicon oxide (SiOₓ), or silicon oxynitride (SiOₓN_{y}). Alternatively, the first gate insulating layer GI1 may include a metal oxide such as, for example, aluminum oxide (AlOₓ), titanium oxide (TiOₓ), zirconium oxide (ZrOₓ), or hafnium oxide (HfOₓ).

The first gate insulating layer GI1 may have a single-layer or multi-layer structure containing one or more inorganic insulating materials.

The gate electrode GE1 may be positioned on the first gate insulating layer GI1.

The gate electrode GE1 may contain a metal or metal alloy such as, for example, copper (Cu), molybdenum (Mo), aluminum (Al), silver (Ag), chromium (Cr), tantalum (Ta), titanium (Ti), or a combination thereof.

The gate electrode GE1 may be composed of a single layer or multiple layers.

A region of the semiconductor layer ACT that overlaps the gate electrode GE in a plane may be a channel region C. The gate electrode GE1 may function as a mask in the process of doping the semiconductor layer ACT. For example, the source region S and drain region D of the transistor may be formed by doping the semiconductor layer ACT with an N-type dopant or a P-type dopant using the gate electrode GE1 as a mask in the doping process. The second gate insulating film GI2 is located on the gate electrode GE1.

The second gate insulating film GI2 may include an inorganic insulating material such as, for example, silicon nitride (SiNₓ), silicon oxide (SiOₓ), or silicon oxynitride (SiOₓN_{y}).

The second gate insulating film GI2 may have a single-layer or multi-layer structure including one or more inorganic insulating materials. In an embodiment of the present invention, the second gate insulating film GI2 may have a multi-layer structure including a silicon oxide (SiOₓ) layer and a silicon nitride (SiNₓ) layer.

The capacitor electrode GE2 may be positioned on the second gate insulating film GI2.

The capacitor electrode GE2 may overlap the gate electrode GE1 to form a capacitor.

The first insulating layer IL1 is located on the capacitor electrode GE2.

The first insulating layer IL1 may include an inorganic insulating material such as, for example, silicon nitride (SiNₓ), silicon oxide (SiOₓ), or silicon oxynitride (SiOₓN_{y}).

The first insulating layer IL1 may have a single-layer or multi-layer structure including the above inorganic insulating material. In an embodiment of the present invention, the first insulating layer IL1 may have a multi-layer structure including a silicon oxide (SiOₓ) layer and a silicon nitride (SiNₓ) layer.

The source electrode SE and the drain electrode DE may be positioned on the first insulating layer IL1.

The source electrode SE and the drain electrode DE are connected to the source region S and the drain region D of the semiconductor layer ACT, respectively, by openings formed in the first insulating layer IL1, the second gate insulating layer GI2, the first gate insulating layer GI1. Accordingly, the semiconductor layer ACT, the gate electrode GE, the source electrode SE, and the drain electrode DE described above form one transistor.

Depending on the embodiment, the transistor may include only the source and drain regions of the semiconductor layer ACT instead of the source electrode SE and drain electrode DE.

The source electrode SE and drain electrode DE may include a material having good conductivity, and may include metals such as, for example, aluminum (Al), copper (Cu), silver (Ag), gold (Au), platinum (Pt), palladium (Pd), nickel (Ni), molybdenum (Mo), tungsten (W), titanium (Ti), chromium (Cr), tantalum (Ta), etc., or metal alloys.

The source electrode SE and drain electrode DE may be composed of a single layer or multiple layers.

According to an embodiment of the present invention, the source electrode SE and drain electrode DE may be composed of a triple layer including an upper layer, a middle layer, and a lower layer, the upper and lower layers may include titanium (Ti), and the middle layer may include aluminum (Al). For example, the source electrode SE and drain electrode DE may have a tri-layer structure of titanium/aluminum/titanium (Ti/Al/Ti) or molybdenum/copper/molybdenum (Mo/Cu/Mo).

The second insulating layer IL2 may be positioned on the source electrode SE and the drain electrode DE.

The second insulating layer IL2 covers the source electrode SE and the drain electrode DE.

The second insulating layer IL2 is used to planarize the surface of the substrate SUB on which the transistor is installed. It may be an organic insulating film, and may include one or more materials selected from a group including, for example, polyimide, polyamide, acrylic resin, benzocyclobutene, and phenol resin. The second insulating layer IL2 may have a flat top surface so that a pixel defining layer PDL and a first electrode E1, which are to be described, located on the second insulating layer IL2 are flat.

The first electrode E1 may be positioned on the second insulating layer IL2.

The first electrode E1 is also called an anode electrode and may be composed of a single layer containing a transparent conductive oxide film or a metal material, or a multiple layer containing these.

The transparent conductive oxide film may include, for example, indium tin oxide (ITO), poly-ITO, indium zinc oxide (IZO), indium gallium zinc oxide (IGZO), and indium tin zinc oxide (ITZO).

Metal materials may include, for example, silver (Ag), molybdenum (Mo), copper (Cu), gold (Au), and aluminum (Al). Alternatively, according to an embodiment of the present invention, the first electrode E1 may include a layer formed of transparent conductive oxide on/below a layer formed of the metal materials. In this case, the first electrode E1 may have a stacked structure including, for example, ITO/Ag/ITO.

The first electrode E1 may be physically and electrically connected to the drain electrode DE through an opening in the second insulating layer IL2. Accordingly, the first electrode E1 may receive the output current transmitted from the drain electrode DE to the light emitting layer EML.

A pixel defining layer PDL and a spacer SPC may be positioned on the first electrode E1 and the second insulating layer IL2.

The pixel defining layer PDL includes a pixel opening OP1 that overlaps at least a portion of the first electrode E1.

The pixel opening OP1 may overlap the center of the first electrode E1 and may not overlap the edge of the first electrode E1. For example, the pixel defining layer PDL may be located on the second insulating layer IL2 to cover an edge of the first electrode E1, and may have the pixel opening OP1 through which central portion of the first electrode E1 is exposed. Accordingly, the size of the pixel opening OP1 may be smaller than the size of the first electrode E1.

The pixel defining layer PDL may define the formation location of the light emitting layer EML so that the light emitting layer EML may be positioned on the exposed portion of the upper surface of the first electrode E1.

The pixel defining layer PDL and spacer SPC may be an organic insulating layer containing one or more materials selected from a group including, for example, polyimide, polyamide, acrylic resin, benzocyclobutene, and phenol resin, and depending on the embodiment, the pixel defining layer PDL may be formed of a black pixel defining layer (BPDL) containing black pigment.

The light emitting layer EML may be located in the pixel opening OP1 partitioned by the pixel defining layer PDL.

The light emitting layer EML may include an organic material that emits red light, green light, blue light, etc. The light emitting layer EML may emit light in response to a potential difference between the first electrode E1 and the second electrode E2.

The light emitting layer EML, which emits red light, green light, and blue light may contain low-molecular or high-molecular organic materials. In an embodiment of the present invention, the light emitting layer EML may include a fluorescent material or a phosphorescent material.

In FIG. 4, the light emitting layer EML is shown as a single layer, but in reality, it may also include auxiliary layers such as an electron injection layer, electron transport layer, a hole transport layer, and a hole injection layer. The hole injection layer and hole transport layer may be located below the light emitting layer EML, and the electron transport layer and electron injection layer may be located above the light emitting layer EML.

The second electrode E2 may be located on the pixel defining layer PDL and the light emitting layer EML.

The second electrode E2 is also called a cathode electrode, and is formed of a transparent conductive layer containing, for example, indium tin oxide (ITO), indium zinc oxide (IZO), indium gallium zinc oxide (IGZO), and/or indium tin zinc oxide (ITZO).

The second electrode E2 may have translucent characteristics, and in this case, it may form a micro-cavity together with the first electrode E1.

According to the micro-cavity structure, the spacing and characteristics between both electrodes allow light of a specific wavelength to be emitted upward, and as a result, red, green, or blue lights may be displayed.

Layers from the first electrode E1 to the second electrode E2 formed in the display area may constitute the light emitting diode ED. The light emitting diode ED may be electrically connected to the transistor. For example, the first electrode E1 of the light emitting diode ED may be physically and electrically connected to the drain electrode DE of the transistor through an opening in the second insulating layer IL2.

The encapsulation layer ENC may be positioned on the second electrode E2. The encapsulation layer ENC may cover the light emitting diode ED to prevent the light emitting diode ED from being damaged or degraded by external impurities.

The encapsulation layer ENC may include at least one inorganic layer and at least one organic layer.

In an embodiment of the present invention, the encapsulation layer ENC may include a first inorganic encapsulation layer EIL1, an organic encapsulation layer EOL, and a second inorganic encapsulation layer EIL2. The organic encapsulation layer EOL may be interposed between the first inorganic encapsulation layer EIL1 and the second inorganic encapsulation layer EIL2. However, this is only an example, and the number of inorganic and organic films co nstituting the encapsulation layer ENC may be changed in various ways. Additionally, depending on the embodiment, a capping layer CPL may be positioned between the encapsulation layer ENC and the second electrode E2.

A lower sensing insulating layer TL1 may be located on the encapsulation layer ENC.

The lower sensing insulating layer TL1 may be formed of an inorganic insulating film, and inorganic materials included in the inorganic insulating film may be at least one of, for example, silicon nitride (SiNₓ), aluminum nitride (AlNₓ), zirconium nitride (ZrNₓ), titanium nitride (TiNₓ), hafnium nitride (HfNₓ), tantalum nitride (TaNₓ), silicon oxide (SiOₓ), aluminum oxide (AlOₓ), titanium oxide (TiOₓ), tin oxide (SnOₓ), cerium oxide (CeOₓ), or silicon oxynitride (SiOₓN_{y}). Alternatively, the lower sensing insulating layer TL1 may be an organic layer including, for example, an epoxy resin, an acrylic resin, or an imide-based resin.

Depending on the embodiment, the lower sensing insulating layer TL1 may be omitted.

A touch sensor may be located on the lower sensing insulating layer TL1. For example, the touch sensor may be located on the encapsulation layer ENC with the lower sensing insulating layer TL1 interposed therebetween, or directly located on the encapsulation layer ENC.

The touch sensor may include a lower sensing electrode part MTL1 and an upper sensing electrode part MTL2.

The lower sensing electrode part MTL1 may include at least one of the plurality of sensing electrodes 520 and 540 described above, the first sensing electrode connecting part 521, and the second sensing electrode connecting part 541.

The upper sensing electrode part MTL2 may include at least one of the plurality of sensing electrodes 520 and 540 described above, the first sensing electrode connecting part 521, and the second sensing electrode connecting part 541.

In an embodiment of the present invention, the upper sensing electrode part MTL2 includes a plurality of sensing electrodes 520 and 540 and a first sensing electrode connection part 521, and the lower sensing electrode part MTL1 includes a second sensing electrode connection part 541, but the present invention is not limited thereto.

By using two layers (e.g., the lower sensing electrode part MTL1 and the upper sensing electrode part MTL2) of the sensing electrodes such as the first sensing electrodes 520 and the second sensing electrodes 540, a resistance of each of the sensing electrodes may be lowered.

The lower sensing electrode part MTL1 may be located on the lower sensing insulating layer TL1.

The first sensing insulating layer TL2 may be located on the lower sensing insulating layer TL1 and the lower sensing electrode part MTL1.

The first sensing insulating layer TL2 may include an inorganic insulating material or an organic insulating material.

The inorganic insulating material may include at least one of, for example, silicon nitride (SiNₓ), aluminum nitride (AlNₓ), zirconium nitride (ZrNₓ), titanium nitride (TiNₓ), hafnium nitride (HfNₓ), tantalum nitride (TaNₓ), silicon oxide (SiOₓ), aluminum oxide (AlOₓ), titanium oxide (TiOₓ), tin oxide (SnOₓ), cerium oxide (CeOₓ), or silicon oxynitride (SiOₓN_{y}).

The organic insulating material may include at least one of, for example, acrylic resin, methacrylic resin, polyisoprene, vinyl resin, epoxy resin, urethane resin, cellulose resin, or perylene resin.

An upper sensing electrode part MTL2 may be positioned on the first sensing insulating layer TL2. The first sensing insulating layer TL2 may be disposed between the lower sensing electrode part MTL1 and the upper sensing electrode part MTL2.

A polarizing layer including a plurality of insulating layers, a linear polarizer, a retardation plate, etc. may be further positioned on the upper sensing electrode part MTL2 and the first sensing insulating layer TL2.

Hereinafter, a composite according to an embodiment of the present invention will be described with reference to FIGS. 5 to 7.

Referring to FIG. 5, the organic encapsulation layer EOL according to an embodiment of the present invention may include a plurality of composites NC.

The plurality of composites NC may be dispersed within the first organic material OM included in the organic encapsulation layer EOL.

The organic encapsulation layer EOL may be formed by curing the first organic material OM in which a plurality of composites NC are dispersed.

The first organic material OM may include at least one of, for example, an acrylate-based compound, an epoxy-based compound, a vinyl-based compound, or a urethane-based compound.

The first organic material OM may form an organic encapsulation layer EOL through a thermal curing process, a photo curing process, etc.

The first organic material OM may have a low viscosity—for example, about 1 cP to about 50 cP. The first organic material OM having the low viscosity may be suitable for ink jet printing. In an embodiment of the present invention, the organic encapsulation layer EOL may be formed by an ink jet printing method. However, the present invention is not limited thereto.

The plurality of composites NC may have an approximately spherical shape, and on average, the diameter of the composites NC may be about 500 nanometers or less.

FIG. 6 is a diagram specifically showing one composite NC.

The composite NC may include deoxyribonucleic acid (D, also known as DNA) in the form of a plurality of nucleotides bound together and a hollow polymer PC.

As shown in FIG. 7, the composite NC may be formed by mixing nucleotides Da which is a unit of deoxyribonucleic acid DNA, and the hollow polymer PC.

Referring again to FIG. 6, the hollow polymer PC may have an empty space inside.

The empty space is referred to as first space SP1.

The hollow polymer PC may include, for example, polystyrene, but the present invention is not limited thereto, and of course, any polymer material that can provide a hollow shape may be used for the hollow polymer PC.

Deoxyribonucleic acid D may be formed by combining nucleotides, which are units of deoxyribonucleic acid DNA. For example, each of the plurality of composites NC may include DNA in which a plurality of nucleotides are bonded together. Each strand of a DNA molecule may be composed of nucleotides bonded together covalently between the phosphate group of one and the deoxyribose sugar of the next.

A plurality of nucleotides may form a deoxyribonucleic acid D with an internal space.

The space contained by deoxyribonucleic acid D may be referred to as the second space SP2.

A plurality of hollow polymers PC may be included in one composite NC.

A plurality of hollow polymers PC may be located in the second space SP2.

A plurality of hollow polymers PC may be spaced apart from or adjacent to each other within the second space SP2. For example, the plurality of hollow polymers PC may be located within the deoxyribonucleic acid D. For example, each of the plurality of composites NC may include the hollow polymer PC and deoxyribonucleic acid D may surround the hollow polymer PC.

According to an embodiment of the present invention, the first organic material OM forming the organic encapsulation layer EOL does not penetrate into the space inside the composite NC and may have a shape that surrounds the composite NC, but the present invention is not limited thereto.

The touch sensitivity SNR of the touch sensor included in the display device may be determined by the following equation (1).

In equation (1), dCm is the change in capacitance value between the detection output electrode and the detection input electrode, and Cb may be determined by equation (2) below. Here, Cb is the capacitance between the second electrode and the touch sensor.

In equation (2), co is the dielectric constant, EMN is the dielectric constant of the organic encapsulation layer, d is the distance between the second electrode and the touch sensor, and A is the area occupied by the electrode.

Since the Cb value is proportional to the dielectric constant value of the organic encapsulation layer, when the dielectric constant value of the organic encapsulation layer is lowered, touch sensitivity may be enhanced by decreasing the Cb value.

$$SNR = \frac{Signal ( dCm )}{Noise ( Cb )} \qquad equation ( 1 )$$

$$Cb ∝ {ε}_{0} \cdot {ε}_{MN} \cdot \frac{A}{d} \qquad equation ( 2 )$$

The free volume of the organic encapsulation layer EOL increases due to the first space SP1 contained by the hollow polymer and the second space SP2 contained by the deoxyribonucleic acid D forming each composite.

According to this, the dielectric constant of the organic encapsulation layer EOL is reduced, and touch sensitivity may be enhanced due to the decrease in the dielectric constant of the organic encapsulation layer EOL, and thus, a display device with enhanced touch sensitivity may be provided.

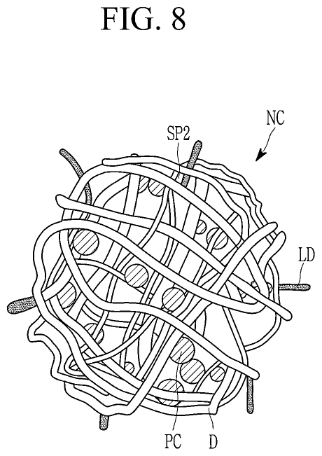

Hereinafter, a composite according to an embodiment of the present invention will be described with reference to FIG. 8.

FIG. 8 is a diagram of a composite according to an embodiment of the present invention.

Referring to FIG. 8, the composite NC according to an embodiment of the present invention may further include a ligand LD bound to the surface of deoxyribonucleic acid D. For example, the ligand LD may be bound to a surface of each of the plurality of composites NC.

The ligand LD may include a compound of a family the same as that of the first organic material OM forming the composite NC.

In an embodiment of the present invention, the ligand LD and the first organic material OM may include at least one of, for example, an acrylate-based compound, an epoxy-based compound, a vinyl-based compound, or a urethane-based compound.

In an embodiment of the present invention, the acrylate-based compound may include a compound represented by Formula 1 below.

The epoxy-based compound may include a compound represented by the following Formula 2.

The vinyl-based compound may include a compound represented by the following Formula 3.

When the ligand LD includes a compound of a type the same as that of the first organic material OM, it may be evenly dispersed in the first organic material OM to provide a stable organic encapsulation layer EOL.

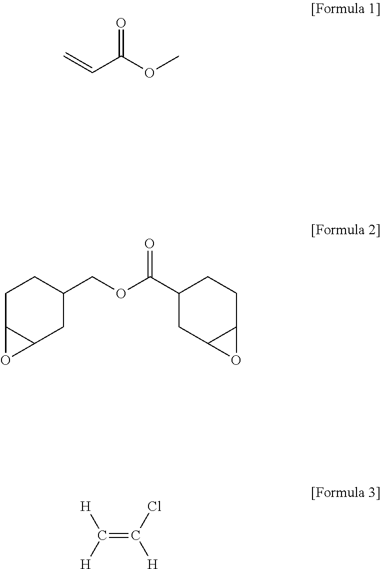

According to the above, the free volume may be increased by the first space SP1 included in the hollow polymer PC and the second space SP2 included in the deoxyribonucleic acid D forming each composite NC.

According to this, the dielectric constant of the organic encapsulation layer is reduced, and the touch sensitivity of the touch sensor is enhanced due to the decrease in dielectric constant of the organic encapsulation layer, and thus, a display device with enhanced touch sensitivity may be provided.

Although the embodiments of the present invention have been described in detail above, the present invention is not limited thereto, and various modifications and enhancements may be made therein by those skilled in the art without departing from the spirit and scope of the present invention as defined in the appended claims.

What is claimed is:

1. A display device, comprising:
a substrate;
a transistor located on the substrate;
a light emitting diode electrically connected to the transistor;
a first inorganic encapsulation layer located on the light emitting diode;
an organic encapsulation layer located on the first inorganic encapsulation layer; and
a second inorganic encapsulation layer located on the organic encapsulation layer,
wherein the organic encapsulation layer includes a plurality of composites, and
each of the plurality of composites includes a plurality of nucleotides and a hollow polymer.

2. The display device of claim 1, wherein
each of the plurality of composites includes deoxyribonucleic acid (DNA) in which the plurality of nucleotides are bonded together.

3. The display device of claim 2, wherein
the deoxyribonucleic acid (DNA) includes an empty space therein.

4. The display device of claim 2, wherein
the hollow polymer is located within the deoxyribonucleic acid (DNA).

5. The display device of claim 1, wherein
the hollow polymer includes polystyrene.

6. The display device of claim 1, wherein
the organic encapsulation layer further includes a first organic material, and
the plurality of composites are dispersed in the first organic material.

7. The display device of claim 6, wherein
the first organic material includes at least one of an acrylate-based compound, an epoxy-based compound, a vinyl-based compound, or a urethane-based compound.

8. The display device of claim 6, wherein
each of the plurality of composites further includes a ligand bound to a surface.

9. The display device of claim 8, wherein
the ligand is bound to a deoxyribonucleic acid (DNA).

10. The display device of claim 8, wherein
the ligand includes a compound of a family the same as that of the first organic material.

11. The display device of claim 8, wherein
the ligand includes at least one of an acrylate-based compound, an epoxy-based compound, a vinyl-based compound, or a urethane-based compound.

12. A display device, comprising:
a substrate;
a transistor located on the substrate;
a light emitting diode electrically connected to the transistor;
an organic encapsulation layer located on the light emitting diode; and
a touch sensor located on the organic encapsulation layer,
wherein the organic encapsulation layer includes a plurality of composites dispersed within the organic encapsulation layer, and
each of the plurality of composites includes a hollow polymer and deoxyribonucleic acid (DNA) surrounding the hollow polymer.

13. The display device of claim 12, wherein
each of the plurality of composites further includes:
a first space included in each of the hollow polymers; and
a second space included in the deoxyribonucleic acid (DNA).

14. The display device of claim 13, wherein
the hollow polymer is located in the second space of the deoxyribonucleic acid (DNA).

15. The display device of claim 12, wherein
the hollow polymer includes polystyrene.

16. The display device of claim 12, wherein
the organic encapsulation layer further includes a first organic material, and
the plurality of composites are dispersed in the first organic material.

17. The display device of claim 16, wherein
the first organic material includes at least one of an acrylate-based compound, an epoxy-based compound, a vinyl-based compound, or a urethane-based compound.

18. The display device of claim 16, wherein
each of the plurality of composites further includes a ligand bound to the surface of the deoxyribonucleic acid (DNA).

19. The display device of claim 18, wherein
the ligand includes a compound of a family the same as that of the first organic material.

20. The display device of claim 18, wherein
the ligand includes at least one of an acrylate-based compound, an epoxy-based compound, a vinyl-based compound, or a urethane-based compound.
